(19) United States
(12) Patent Application Publication
(10) Pub. No.: US 2007/0119293 A1
(43) Pub. Date: May 31, 2007

(54) Balloon instrument and method of making same

(76) Inventors: James Rouvelle, Baltimore, MD (US); Richard Murphy, Pennington, NJ (US)

Correspondence Address: KAREN B. TRIPP, ATTORNEY AT LAW, P.O. BOX 1301, HOUSTON, TX, 77251, US

(21) Appl. No.: 10/576,394

(22) PCT Filed: Oct. 20, 2004
(86) PCT No.: PCT/US04/34821

§ 371 Date: May 19, 2006

Related U.S. Application Data
(60) Provisional application No. 60/513,104, filed on Oct. 20, 2003.

(51) Int. Cl. G10H 1/46; G10H 7/00; H03G 3/00

(52) U.S. Cl. 84/633

(57) ABSTRACT

A device capable of responding to an outside stimulus is disclosed. The device includes a volume at least partially defined by the device with conductive circuitry electrically coupled to the volume. This conductive circuitry suitable for conducting an electrical charge accumulated on the volume in response to the outside stimulus. The device further includes feedback circuitry electrically coupled to the conductive circuitry. This feedback circuitry suitable for converting the electrical charge into a drive signal. The device further includes feedback driven by the drive signal. This feedback suitable for providing feedback directly indicative of the outside stimulus.

### FIELD OF THE INVENTION

The present invention is directed to interactive instruments, and more particularly interactive instruments that produce feedback associated with an external stimulus.

### SUMMARY OF THE INVENTION

A device capable of responding to an outside stimulus is disclosed. The device includes: a volume at least partially defined by the device; conductive circuitry electrically coupled to the volume, the conductive circuitry suitable for conducting an electrical charge accumulated on the volume in response to the outside stimulus; feedback circuitry electrically coupled to the conductive circuitry, the feedback circuitry suitable for converting the electrical charge into a drive signal; and, feedback driven by the drive signal, the feedback suitable for providing feedback directly indicative of the outside stimulus.

Further, a device capable of responding to an outside stimulus is disclosed. The device includes: a volume at least partially defined by the device; a conductive means electrically coupled to the volume, the conductive means suitable for conducting an electrical charge accumulated on the volume in response to the outside stimulus; a feedback means electrically coupled to the conductive means, the feedback means suitable for converting the electrical charge into a drive signal; and, feedback driven by the drive signal, the feedback suitable for providing feedback directly indicative of the outside stimulus.

Further, a device having a volume at least partially defined by the device, the device being capable of responding to an outside stimulus is disclosed. The device includes: conductive circuitry electrically coupled to the volume, the conductive circuitry suitable for conducting an electrical charge accumulated on the volume in response to the outside stimulus; feedback circuitry electrically coupled to the conductive circuitry, the feedback circuitry suitable for converting the electrical charge into a drive signal; and, feedback driven by the drive signal, the feedback suitable for providing feedback directly indicative of the outside stimulus.

A method of providing feedback associated with the contact of a device is also disclosed. The method includes: monitoring the device for external contact; inputting a signal responsive to the external contact; switching an output in relation to the input signal; producing an amplified signal associated with the output; generating feedback from the amplified signal, wherein the feedback is directly indicative of the external contact.

### BRIEF DESCRIPTION OF THE FIGURES

Understanding of the present invention will be facilitated by consideration of the following detailed description of the preferred embodiments of the present invention taken in conjunction with the accompanying drawings, in which like numerals refer to like parts, and:

FIG. 1 is a diagrammatical view of the instrument according to an aspect of the present invention;

FIG. 2 is a flow diagram of the method of making or creating feedback associated with the instrument of FIG. 1; and,

FIG. 3 is a diagrammatical view of the instrument according to an aspect of the present invention.

### DETAILED DESCRIPTION OF THE INVENTION

It may be to be understood that the figures and descriptions of the present invention have been simplified to illustrate elements that are relevant for a clear understanding of the present invention, while eliminating, for purposes of clarity, many other elements found in a electronic feedback system. Those of ordinary skill in the art will recognize that other elements are desirable and/or required in order to implement the present invention. However, because such elements are well known in the art, and because they do not facilitate a better understanding of the present invention, a discussion of such elements may be not provided herein.

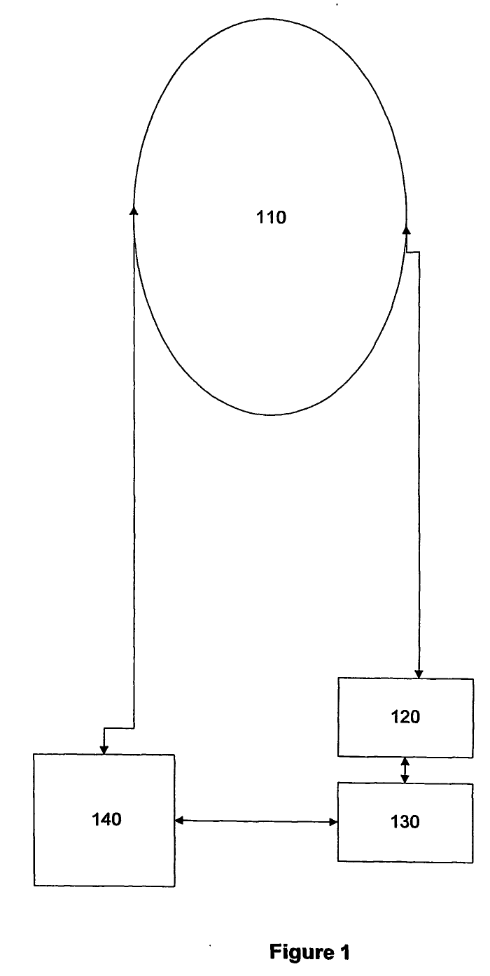

Referring now to FIG. 1, there is shown an instrument 100 according to an aspect of the present invention. Instrument 100, as may be seen in FIG. 1, may include a volume 110, a conductive circuitry 120 electrically connected to volume 110, an acoustical circuitry 130 electrically connected to conductive circuitry 120, and a feedback 140 electrically connected to acoustical circuitry 130.

Volume 110 may take the form of a balloon for example, such that when the balloon is inflated it defines a volume. Additionally, according to an aspect of the present invention, volume may be formed from a material that has electrical properties capable of sustaining and transferring electrical signals. Such materials may be known to those possessing an ordinary skill in the pertinent arts. Such materials may include mylar or other metalized material, for example. As will be discussed hereinbelow, the properties of the material in volume 110 may relate to the signals delivered or received by conductive circuitry 120 and/or acoustical circuitry 130. In particular, in response to an outside stimulus, volume 110 may produce an electrical charge accumulated on the surface of volume 110 and transmitted therefrom to conductive circuitry 120 and/or acoustical circuitry 130. Each element of the present invention may be physically located within volume 110, or alternatively, each element may be located external to volume 110. Additionally, a subset of the elements of the present invention may be located within volume 110 while other elements may be located external to volume 110.

In the alternative, volume 110 may be made from any substance suitable for defining a volume. According to an aspect of the present invention volume 110 may provide a resonance for feedback 140 discussed hereinbelow. If the substance of volume 110 does not possess electrical properties suitable for the transferring of electrical signals as discussed herein, an alternative conduction system may be used. For example, distinct regions or discs electrically connected to circuitry 120 and/or circuitry 130 may be adhered to volume 110 thereby creating a signal transmission mechanism of the present invention.

In an embodiment of the present invention, instrument 100 may configured with volume 110 including a mylar or metalized nylon balloon outfitted with piezo elements. These elements may be of various or varied sizes and shapes and may be in the range of approximately one inch in diameter up to several inches in diameter depending on the size of volume 110. In general, the shape of the elements does not have a bearing on the operation of the present invention, but may be guided by design appeal. These elements may be attached to volume 110 by any method known to those possessing an ordinary skill in the pertinent arts. In particular, an adhesive, which may be conductive or non-conductive, such as an acrylic polymer, propylene glycol, or polyethylene glycol, or other adhesive based substance, for example, may be used to attach the elements to each side of volume 110. In connecting the elements to volume 110, performance may be heightened when using a volume 110 with conductive properties, if a conductive pathway exists between element and volume 110. According to an aspect of the present invention, any number of elements may be utilized with a minimum of one per side of volume 110. Of importance in the present invention, is that at least two sides of volume 110 exist. For example, the shiny, conductive sides may face out, and the dull, non-conductive sides may be adhered to each other. This configuration may create two distinct areas capable of conducting electricity, but not in electrical connection with the other area.

Conductive circuitry 120 may be electrically connected to volume 110. Conductive circuitry 120 may include an oscillator, comprised of a transistor, resistors, and capacitor, such as a driver circuit, for example. In particular, conductive circuit 120 may take the form of a simple oscillator circuit suitable for switching the output signal on and off in response to a given drive signal. According to an aspect of the present invention, multiple conductive circuits may be connected in series on one or both sides of the volume 110. Such a configuration may create several distinct areas on volume 110 and may be electrically connected to independent feedback 140, as will be discussed hereinbelow.

Acoustical circuitry 130 may be electrically connected to conductive circuitry 120. Acoustical circuitry 130 may include an amplifier circuit. Such an amplifier circuit may connect conductive circuitry 120 from multiple areas of volume 110. Acoustical circuitry 130 may include a simple operational amplifier, such as an audio amplifier like LM386, for example. Such an operational amplifier may produce signals with an average output of 1 watt, for example. For example, signals emanating from one area of volume 110 may be electrically directed through conductive circuitry 120 to an input of acoustical circuit 130, while signals emanating from another area of volume 110 may be electrically directed through conductive circuitry 120 to an output of acoustical circuit 130. Aspects or elements of acoustical circuitry 130 may be common with conductive circuitry 120. The variation in amplification may be directly related to the feedback signal produced. For example, the greater the amplification, the louder the volume of a audio feedback.

Feedback 140 may be electrically connected to acoustical circuitry 130. Feedback may include a type of response associated with signals discussed hereinabove. Response may take the form of a visual emission such a light, or color change, a noise emission, or frequency change or volume change of a noise produced, or an odor emission, for example. Feedback 140 may be utilized to initiate or create a variety of sounds that emanate from volume 110 utilizing audio circuitry, for example. In response to a user touching elements discussed hereinabove, one element may become a speaker, and the other a transducer. As touch of the user varies, the electronic coupling may change, and the pitch, rhythm, loudness, and timbre emanating from elements may change. Further, multiple external stimuli creating a chain of stimuli in contact with elements and volume 110 may generate feedback which may increase or decrease with the conductive contact chain created. For example, in the case of a human stimulus, feedback 140 may be associated with the PH level on the skin of the user contacting volume 110. Sound from the element acting as a speaker may resonate through volume 110. Volume 110 may act as an acoustic resonator in addition to a conductive volume. This combination of touch and sound may create a positive feedback loop.

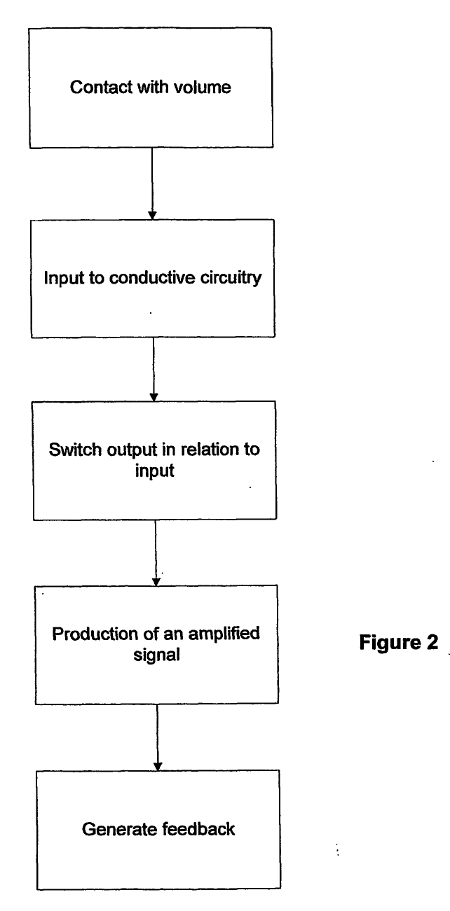

FIG. 2 is a flow diagram of the method 200 of making or creating feedback associated with the instrument of FIG. 1. In particular, contact 210 with volume may provide an input 220 to conductive circuitry. Conductive circuitry may switch 230 its output in relation to input 220. Switched output 230 may be input into acoustical circuitry, thereby producing 240 an amplified signal. Amplified signal may be provided to feedback, thereby generating 250 the feedback.

In this regard, interaction with external sources such as humans for example may cause feedback. Pressure on a piezo transducer affixed to one of the mounted volumes, while simultaneously holding another piezo element may create a feedback loop wherein the natural electrical resistance of the external source has a direct effect on the feedback produced. The transducers may convert contact into electrical impulse, which may be amplified and fed into an oscillator. By varying the external contact, a myriad of feedback variations such as resonance through the volume may be achieved. Generally, the feedback loop requires completion of the circuit by an external source.

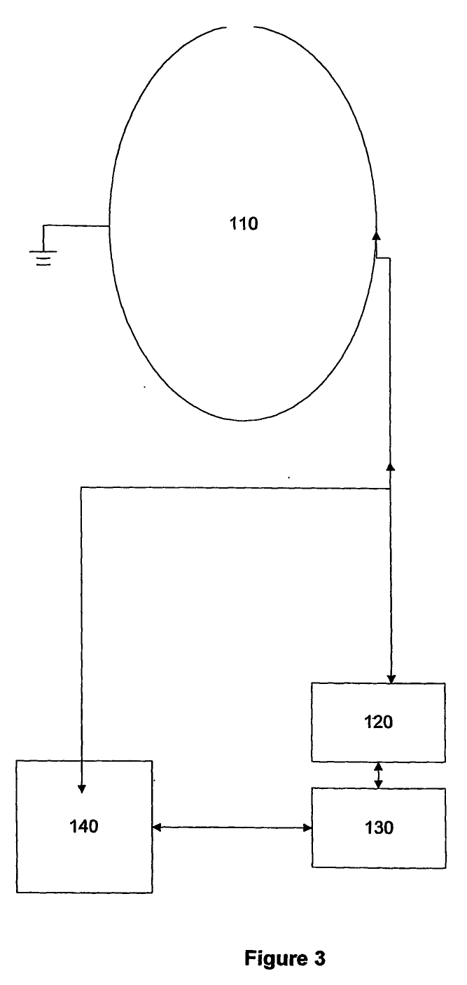

Referring now to FIG. 3, there is shown an instrument 300 according to an aspect of the present invention. Instrument 300 may incorporate many of the elements discussed hereinabove with respect to instrument 100. Instrument 300 may utilize a single element on one side of volume 110, while the other side of volume 110 may be grounded to conductive circuitry 120. The remaining portions of conductive circuitry 120 may be electrically connected to a small piece of conductive foam, such as if covered in mylar, for example, and may be attached to volume 110. A varying external stimulus pressure on volume 110 may cause feedback 140 to become electrically excited and feedback may emit a varied feedback method as describe hereinabove.

Additionally, the present invention may also include circuitry, such as a micro-controller for example, that is capable of listening to the sounds created within instrument 100. Such a circuit may be able to respond to the created sounds by deflating/inflating instrument 100 or volume 110, for example. This deflating or inflating may be achieved by electrically connecting the circuit to a blower and solenoid motor suitable for inflating or deflating instrument 100 or volume 110 in response to the circuit signals. The creation of sounds as a middle point in the feedback may be circumvented by driving a micro-controller with the signal output from acoustical circuit. In this way, the inflating/deflating may occur without sound.

Those of ordinary skill in the art will recognize that many modifications and variations of the present invention may be implemented. The foregoing description and the following claims are intended to cover all such modifications and variations.

What is claimed is:

1. A device capable of responding to an outside stimulus, said device comprising:
a volume at least partially defined by the device;
conductive circuitry electrically coupled to said volume, said conductive circuitry suitable for conducting an electrical charge accumulated on said volume in response to the outside stimulus;
feedback circuitry electrically coupled to said conductive circuitry, said feedback circuitry suitable for converting the electrical charge into a drive signal; and,
feedback driven by the drive signal, said feedback suitable for providing feedback directly indicative of the outside stimulus.

2. The device of claim 1, wherein said volume is defined by a balloon.

3. The device of claim 1, wherein said volume is defined by a material with electrical properties capable of sustaining and transferring electrical signals.

4. The device of claim 1, wherein at least one of said conductive circuitry and said feedback circuitry are located substantially within said volume.

5. The device of claim 1, wherein at least one of said conductive circuitry and said feedback circuitry are located substantially outside said volume.

6. The device of claim 1, wherein said volume provides a resonance for said feedback.

7. The device of claim 1, wherein said conductive circuitry includes distinct regions adhered to said volume suitable for creating a conductive signal path.

8. The device of claim 1, wherein said conductive circuitry includes at least an oscillator.

9. The device of claim 1, wherein said conductive circuitry is suitable for switching the output signal on and off in response to a given outside stimulus.

10. The device of claim 1, wherein said acoustical circuitry includes at least an amplifier circuit.

11. The device of claim 1, wherein said feedback circuitry includes at least an operational amplifier.

12. The device of claim 11, wherein said operational amplifier produces signals with an average output of approximately one watt.

13. The device of claim 1, wherein said feedback is substantially a visual emission.

14. The device of claim 13, wherein said visual emission is light emission.

15. The device of claim 13, wherein said visual emission is a color change.

16. The device of claim 1, wherein said feedback is substantially a noise emission.

17. The device of claim 16, wherein said noise emission includes at least one of a frequency change and volume change.

18. The device of claim 1, wherein said feedback is substantially an odor emission.

19. The device of claim 1, wherein the outside stimulus includes a PH level of the outside stimulus.

20. The device of claim 1, wherein said volume at least partially acts as an acoustic resonator.

21. The device of claim 1, wherein said feedback includes varying a pressure inside said volume.

22. The device of claim 1, wherein said outside stimulus includes sound.

23. A device capable of responding to an outside stimulus, said device comprising:
a volume at least partially defined by the device;
a conductive means electrically coupled to said volume, said conductive means suitable for conducting an electrical charge accumulated on said volume in response to the outside stimulus;
a feedback means electrically coupled to said conductive means, said feedback means suitable for converting the electrical charge into a drive signal; and,
feedback driven by the drive signal, said feedback suitable for providing feedback directly indicative of the outside stimulus.

24. A device having a volume at least partially defined by the device, said device being capable of responding to an outside stimulus, said device comprising:
conductive circuitry electrically coupled to said volume, said conductive circuitry suitable for conducting an electrical charge accumulated on said volume in response to the outside stimulus;
feedback circuitry electrically coupled to said conductive circuitry, said feedback circuitry suitable for converting the electrical charge into a drive signal; and,
feedback driven by the drive signal, said feedback suitable for providing feedback directly indicative of the outside stimulus.

25. A method of providing feedback associated with the contact of a device, said method comprising:
monitoring said device for external contact;
inputting a signal responsive to the external contact;
switching an output in relation to said input signal;
producing an amplified signal associated with said output;
generating feedback from said amplified signal, wherein said feedback is directly indicative of the external contact.
